(19) United States
(12) Patent Application Publication
(10) Pub. No.: US 2020/0144443 A1
(43) Pub. Date: May 7, 2020

(54) METHOD FOR PRODUCING A PHOTODIODE AND PHOTODIODE

(71) Applicant: Commissariat A L'Energie Atomique et aux Energies Alternatives, Paris (FR)

(72) Inventors: Georgio EL ZAMMAR, Grenoble Cedex 9 (FR); Rami Khazaka, Grenoble Cedex 9 (FR); Sylvie Menezo, Grenoble Cedex 9 (FR); Vincent Reboud, Grenoble Cedex 9 (FR)

(73) Assignee: Commissariat A L'Energie Atomique et aux Energies Alternatives, Paris (FR)

(21) Appl. No.: 16/675,495

(22) Filed: Nov. 6, 2019

(30) Foreign Application Priority Data
Nov. 7, 2018 (FR) 18 60256

(51) Int. Cl. H01L 31/18; H01L 31/105

(52) U.S. Cl. CPC H01L 31/1808; H01L 31/1896; H01L 31/105; H01L 31/1812

(57) ABSTRACT

A method for producing a photodiode including an absorption region A made from Ge interposed between two contact regions. The absorption region A is formed directly on a layer of silicon oxide through a first lateral epitaxial growth followed by a second vertical epitaxial growth. Advantageously, a cavity is formed between the contact regions by encapsulation and etching, so as to guide the first lateral growth of Ge. This first growth forms a base layer having a reduced level of structural defects. The second growth of Ge is done next from this base layer, in order to obtain a structure layer having a greater thickness while keeping a reduced level of structural defects. The absorption region A is advantageously formed in a stack of base and structure layers, so as to obtain a GeOI lateral photodiode.

### TECHNICAL FIELD OF THE INVENTION

The invention relates to the field of photonics and optoelectronics. It finds at least one particularly advantageous application in the field of photodetectors. It will find an advantageous but non-limitative application in the production of photodiodes, in particular based on germanium.

### PRIOR ART

In the field of photonics on silicon, a photodetector is an essential optoelectronic component of optical communication systems that can be integrated in CMOS technology.

One challenge related to the manufacture of photodetectors is increasing the sensitivity of light detection.

A principle of detecting light in a photodetector or a photodiode is as follows:

A photon is absorbed in the absorption region of the photodiode. The absorption of this photon generates an electron-hole pair. The electron and the hole, referred to as electrical charge carriers, can then be collected via electrodes or contact regions. The electric current generated by these carriers can then be used for detecting the photon giving rise to the phenomenon.

A photodiode architecture using this principle is a p-i-n photodiode comprising an absorption region made from a non-doped material (i standing for intrinsic) interposed between two contact regions made from a doped material (p and n standing for the corresponding doping type).

Because of its absorption and conduction properties, and its compatibility with CMOS technologies, germanium (Ge) is generally used for manufacturing Ge photodiodes having a conventional Ge-p/Ge-i/Ge-n architecture.

One particularly advantageous possibility for increasing the detection sensitivity of photodiodes is to improve the confinement of the photons in the absorption region of the photodiode.

Confining the photons in the absorption region may result from an optical index contrast between the material of the absorption medium and the surrounding materials.

The document “Development of avalanche photodiodes in Ge on Si for high-speed weak-signal detection, L. Virot, Université Paris Sud—Paris XI, 2014” discloses for example a lateral p-i-n photodiode architecture using silicon (Si) and germanium (Ge).

Such a photodiode illustrated in FIG. 1 has a double Si-p/Ge-i/Si-n heterojunction. This architecture allows confinement of the light that is improved compared with a conventional Ge photodiode.

The absorption region A interposed between the contact regions 1 and 2 of this double heterojunction photodiode is formed by growth of the Ge 3 from a germination layer 111 made from Si.

This manufacturing method gives rise to optical losses at the germination layer 111 that impair the optical confinement in the absorption region A.

Moreover, a dislocation region is present at the Si/Ge interface between the germination layer 111 and the absorption region A.

Threading dislocations, that is to say ones propagating in the third direction, generate a dark current limiting the low-voltage detection performance of the photodiode.

Integrating such a photodiode by a method of transferring onto another substrate is also difficult to implement. The integration of such a photodiode with other components is limited.

An object of the present invention is to overcome at least some of the disadvantages mentioned above.

According to a particular aspect, an object of the present invention is to propose a method for producing a lateral photodiode for optimising the optical confinement in the absorption region of the photodiode.

According to another aspect, an object of the present invention is to propose a method for producing a lateral photodiode aimed at reducing the amount of threading dislocations in the absorption region of the photodiode.

The other objects, features and advantages of the present invention will emerge from an examination of the following description and the accompanying drawings. Naturally other advantages may be incorporated.

### SUMMARY OF THE INVENTION

To achieve this objective, a first aspect of the invention relates to a method for producing a photodiode comprising a first contact region, a second contact region and an absorption region all juxtaposed so as to lie parallel in a first direction, said absorption region being situated between the first and second contact regions along a second direction.

This method comprises the following steps:
Providing a first substrate comprising a stack in a third direction of a first layer based on a first material on a second layer based on a second material different from the first material,
Forming the first contact region at the first layer,
Forming the second contact region at the first layer,
Forming the absorption region at the first layer.

Advantageously but non-limitatively, the formation of the absorption region comprises at least a first growth of a base layer, referred to as lateral growth, followed by at least one second growth of a structure layer, referred to as vertical growth.

The first growth comprises at least the following successive steps:
Removing the first material in the absorption region over the entire thickness of the first layer so as to expose a bottom face based on the second material, and at least one face based on the first material substantially normal to the basal plane, referred to as the lateral face, having an edge in contact with said exposed bottom face,
Forming the base layer made from a third material by epitaxial growth of said third material from the at least one lateral face, said growth being mainly directed in the second direction and at least partially guided by at least one wall parallel to the basal plane, so that the base layer covers all the bottom face,

the second growth comprising the following successive steps:
Exposing a top face of the base layer parallel to the basal plane,
Forming the structure layer from a fourth material by epitaxial growth on said fourth material in the third direction from the top face of the base layer.

This method makes it possible to obtain a stack of layers comprising the base layer and the structure layer, directly in contact with the second material.

The epitaxial growth in the second direction making it possible to form the base layer is referred to as the lateral epitaxial growth.

The epitaxial growth in the third direction making it possible to form the structure layer is said to be the vertical epitaxial growth.

The lateral epitaxial growth over the entire bottom face based on the second material advantageously makes it possible to dispense with a germination layer on said bottom face for growth of the third material.

The base layer issuing from this lateral epitaxial growth is preferably thin, for example between 10 nm and 50 nm, so as to reduce the level of dislocations of this base layer, that is to say so as to optimise the crystalline quality of this base layer.

According to one possibility, the fourth material is based on the third material or identical to the third material.

Consequently the vertical epitaxial growth of the fourth material on the top face of the base layer makes it possible to obtain a structure layer having a thickness of material based on the third material that is greater while keeping optimum crystalline quality for the structure layer. The vertical epitaxial growth can therefore be done by homoepitaxy.

The vertical epitaxial growth is done for a fourth material having a mesh mismatch with the third material that is preferably less than 0.2%.

The amount of threading dislocations is thus reduced both in the base layer and in the structure layer.

Advantageously, the absorption region is formed in the stack of base and structure layers, preferably over the entire height of the stack.

The absorption region is thus formed directly on the second layer of the substrate without having recourse to an intermediate germination layer.

The optical confinement in the absorption region of the photodiode can thus be improved by eliminating the optical losses caused by the germination layer.

Moreover, the crystalline quality of the absorption region is optimised. The reduction in the amount of dislocations, in particular of threading dislocations, in the absorption region in the end makes it possible to reduce the low-voltage dark current of the photodiodes.

According to the preferred possibility, the third material is based on germanium (Ge), for example germanium or a germanium-tin alloy (GeSn). The fourth material may be germanium, germanium-tin, gallium arsenide or indium phosphide for example.

The method according to the invention consequently makes it possible to obtain a local stack of the GeOI type (according to the English acronym “Germanium On Insulator”).

The optical index contrast is thus optimised and the confinement of the photons in the absorption region in the third direction is improved.

Furthermore, the relative arrangements of the contact and absorption regions confers a so-called lateral architecture on the photodiode.

The method according to the invention therefore makes it possible to obtain GeOI p-i-n lateral photodiodes, for example a p-i-n photodiode with an Si—Ge—Si double heterojunction, having optimised crystalline quality.

Such photodiodes also constitute a separable aspect of the invention.

According to a preferred embodiment of the invention, the base layer is grown in a previously formed cavity.

In particular, this cavity comprises the at least one lateral face, a bottom wall and a top wall. The bottom and top walls are based on a dielectric material taken between a silicon oxide and a silicon nitride. The lateral epitaxial growth mainly in the second direction is consequently constrained in the first direction. The formation of the base layer is thus better controlled and the crystalline quality thereof improved.

The photodiode produced by the method according to the invention can advantageously equip a photodetector in the silicon photonics field.

A separable second aspect of the invention relates to a photodiode comprising a first contact region, a second contact region and an absorption region all formed in a first layer based on the first material and juxtaposed so as to extend parallel in a first direction, said absorption region being situated between the first and second contact regions along a second direction, the first layer being in contact with a second layer based on a second material different from the first material, in a third direction perpendicular to the first and second directions.

Advantageously, the absorption region is formed directly in contact with the second material of the second layer in a thickness of the first layer, preferably over the entire thickness of the first layer, and comprises at least one third material different from the first and second materials.

Advantageously, at least one from the first and second contact regions has a step facing the other one from the first and second contact regions, said step bearing on the second layer and being situated between a first layer and the absorption region.

Such a lateral photodiode makes it possible to obtain the optical confinement in the absorption region of the photodiode.

In particular, the contrast in index between the second material and the at least one third material may advantageously be greater than the contrast in index between the first material and the at least one third material.

According to one possibility, the first material is silicon or germanium, the second material is a dielectric material such as a silicon oxide, and the at least one third material is germanium or a germanium-tin alloy or a silicon-germanium-tin alloy.

The photodiode according to the invention can therefore advantageously be a GeOI lateral photodiode in which the absorption region made from Ge is directly in contact with the silicon oxide of the underlying second layer. The photodiode according to the invention can thus be a p-i-n lateral photodiode with a Ge—GeSn—Ge double heterojunction in which the GeSn absorption region is directly in contact with the silicon oxide of the underlying second layer.

The step may advantageously form a nucleus for a lateral epitaxial growth of the third material in the second direction. Such a growth makes it possible to form a base layer from this third material having a reduced amount of dislocations.

This step preferably has a thickness less than the thickness of the first layer and preferably between 10 nm and 50 nm.

Consequently the absorption region extending over the entire thickness of the first layer comprises the base layer and at least one structure layer made from a fourth material, or based on a third material, on said base layer so as to obtain the required thickness.

A structure layer based on the third material can advantageously be produced by homoepitaxy of the third material on the base layer in the third direction. This makes it possible to form a structure layer from this third material having a reduced level of dislocations.

Such a photodiode therefore advantageously comprises an absorption region having both a reduced level of dislocations and a high thickness of the third material, for example over the entire thickness of the first layer.

The photodiode according to the invention can be produced by the method according to the first aspect of the invention.

The photodiode according to the invention can advantageously equip a photodetector in the silicon photonics field.

### BRIEF DESCRIPTION OF THE FIGURES

The aims, objects, features and advantages of the invention will emerge more clearly from the detailed description of embodiments thereof that are illustrated by the following accompanying drawings, in which:

FIG. 1 is a view in cross section of a double-heterojunction lateral photodiode according to the prior art;

FIGS. 2 to 13B illustrate steps of producing a photodiode according to a first embodiment of the present invention;

FIGS. 14 to 16 illustrate steps of producing a photodiode according to a second embodiment of the present invention;

FIG. 17 shows a view by high-resolution transmission electron microscopy (HRTEM) in cross section of a base layer made from Ge according to an embodiment of the present invention.

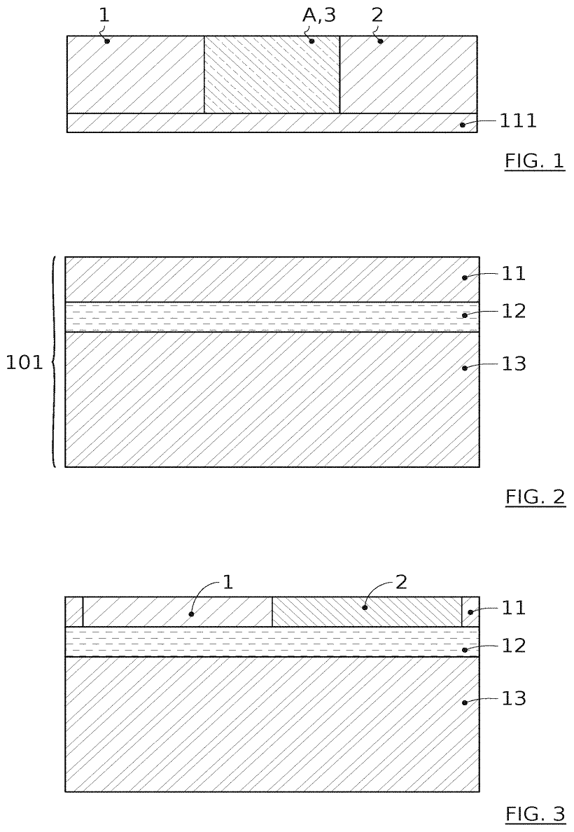

The figures bearing the same number indexed A and B illustrate the same method step respectively in cross section and in plan view.

The drawings are given by way of examples and are not limitative of the invention. They constitute outline schematic representations intended to facilitate understanding of the invention and are not necessarily to the scale of practical applications. In particular, the thicknesses and dimensions of the various layers and portions of the photodiodes illustrated do not represent reality.

### DETAILED DESCRIPTION OF THE INVENTION

Before beginning a detailed review of embodiments of the invention, it is stated that the invention according to the first aspect thereof optionally comprises in particular the following optional features that can be used in association or alternatively:
The first growth comprises the following substeps for removing the first material over the entire thickness of the first layer:
   Removing the first material of the first layer while keeping a sacrificial layer based on the first material on the second layer, said sacrificial layer having a residual thickness e in the third direction and a width w in the second direction,
   Encapsulating the sacrificial layer with an encapsulation layer made from an encapsulation material different from the first material,
   Forming at least one opening through the encapsulation layer so as to expose a region of the sacrificial layer,
   Forming a cavity of width ws such that ws≤w by removing the first material over the entire residual thickness of the sacrificial layer (30) through the at least one opening, so as to expose the bottom face based on the second material, the at least one lateral face and a face of the encapsulation layer, the cavity comprising said at least one lateral face, the bottom wall formed by said bottom face and a top wall parallel to the basal plane and based on the encapsulation material formed by said face of the encapsulation layer,
so that the epitaxial growth making it possible to form the base layer is at least partially guided by said bottom and top walls, the base layer having a thickness equal to the residual thickness e.
The formation of the at least one opening is configured so that the exposed region of the sacrificial layer is situated outside the absorption region, preferably at a distance greater than 1 μm from the absorption region.
the second growth further comprises, before the formation of the structure layer, the following step:
   Forming at least one lateral layer having lateral walls substantially normal to the basal plane made from a material different from the first material, said at least one lateral layer bearing on a face parallel to the basal plane comprising the top face of the base layer,
so that the epitaxial growth making it possible to form the structure layer is at least partially guided by said lateral walls.
the second growth comprises the following substeps for forming the at least one lateral layer:
   Partially removing the encapsulation layer so as to expose the face parallel to the basal plane comprising the top face of the base layer, leaving part of the encapsulation material so as to form the at least one lateral layer.
the second growth comprises the following substeps performing the at least one lateral layer:
   Totally removing the encapsulation layer so as to expose the face parallel to the basal plane comprising the top face of the base layer,
   Forming the at least one lateral layer from a material taken from a silicon oxide and a silicon nitride.
The first, third and fourth materials each have a crystallographic structure of the cubic type, and the first direction corresponds to a crystallographic orientation of type [100], the second direction corresponds to a crystallographic orientation of type [010], and the third direction corresponds to a crystallographic orientation of type [001].
The removal of the first material during the formation of the cavity is done by etching, said etching being configured so as to produce an etching rate at least 25% greater in crystallographic directions [110] and [1-10] than in crystallographic directions [010] and [100] of the first material of the first layer, and preferably at least 35% greater.
The width ws of the cavity is strictly less than the width w of the sacrificial layer, preferably w−ws≥125 nm, so that the sacrificial layer forms at least one step between the second layer and the first layer.
The at least one lateral layer comprises a first lateral layer in contact with at least one face of the first contact region substantially normal to the second direction, said first lateral layer having a width w1 in the second direction greater than or equal to 10 nm and/or less than or equal to 100 nm.
The at least one lateral layer comprises a second lateral layer in contact with at least one face of the second contact region substantially normal to the second direction, said second lateral layer having a width w2 in the second direction greater than or equal to 10 nm and/or less than or equal to 100 nm.
The base layer has a thickness e in the third direction greater than or equal to 10 nm and/or less than or equal to 50 nm.
The first substrate comprises a third layer, so that the second layer is interposed between the first and third layers in the third direction, the method further comprising a sequence of steps of flipping the photodiode on a second substrate, said sequence comprising the following steps:
   Providing a second substrate,
   Bonding, by molecular adhesion, the second substrate to the first substrate in the third direction, the first layer of the first substrate being turned facing the second substrate,
   Removing the third layer of the third substrate.
The method further comprises a formation, at the first layer, of a waveguide in direct coupling with the absorption region.
The at least one opening has a closed contour and is distant from the first contact region by a distance d in the second direction such that 0.6 μm<d<1.5 μm and preferably 1.1 μm<d<1.5 μm.
The at least one lateral face based on the first material comprises a first lateral face and a second lateral face opposite the first lateral face, and at least one opening is situated at equal distances from said first and second lateral faces in the second direction.
The epitaxial growth for forming the base layer is done at a first temperature T1 lying between 300° C.<T1<450° C.
The epitaxial growth for forming the structure layer is done at a second temperature T2 lying between 300° C. and 750° C.
The first material is silicon or germanium, the second material is a dielectric material such as silicon oxide, the third material is taken from germanium or a germanium-tin alloy, and the fourth material is taken from germanium, germanium-tin, gallium arsenide or indium phosphide.
The formation of at least one from the first and second contact regions is done by ion implantation prior to the formation of the absorption region.
   The invention according to its second aspect comprises optionally in particular the following optional features that can be used in association or alternatively:
The first, second and third materials respectively have first, second and third refractive indices n1, n2, n3 such that n2<n1<n3 and preferably n2≤2, n1≥3 and n3≥3.5.
The step has a thickness e in the third direction greater than or equal to 10 nm and/or less than or equal to 50 nm.
The step has a width wi in the second direction greater than or equal to 10 nm and/or less than or equal to 100 nm.
The step has a thickness less than that of the absorption region.
The step has a thickness less than that of a main portion of the at least one from the first and second contact regions carrying the step.
The photodiode further comprises at least one lateral layer bearing on the step and situated between the first layer and the absorption region, said at least one lateral layer being made from a material taken from a silicon oxide and a silicon nitride.
The first material is silicon or germanium, the second material is a dielectric material such as a silicon oxide, and the at least one third material is germanium or a germanium-tin alloy.
The index contrast between the second material and the at least one third material is greater than the index contrast between the first material and the at least one third material.

Hereinafter, an absorption region is a region configured to at least partly absorb the photons of an incident light flow and in response to generate electric charge carriers, said generation of charges resulting from the absorption phenomenon. The absorption region is preferably made from germanium or germanium-tin alloy in the present application.

In the context of the present invention, the relative arrangement of a third region interposed between a first region and a second region does not necessarily mean that the regions are directly in contact with each other, but signifies that the first region is either directly in contact with the first and second regions or separated therefrom by at least one other region or at least one other element.

The steps of formation of the regions, in particular the contact and absorption regions, should be taken in the broad sense: they may be performed in a plurality of substeps that are not necessarily strictly successive.

In the present invention, doping types are indicated. These dopings are non-limitative examples. The invention covers all the embodiments in which the dopings are reversed. Thus, if an example embodiment mentions for a first region a p doping and for a second region an n doping, the present description then, implicitly at least, describes the opposite example in which the first region has an n doping and the second region a p doping.

The doping ranges associated with the various doping types indicated in the present application are as follows:
p++ or n++ doping: greater than 1×10²⁰ cm⁻³
p+ or n+ doping: 1×10¹⁸ cm⁻³ to 9×10¹⁹ cm⁻³
p or n doping: 1×10¹⁷ cm⁻³ to 1×10¹⁸ cm⁻³
intrinsic doping: 1.10¹⁵ cm⁻³ to 1.10¹⁷ cm⁻³

Hereinafter, the following abbreviations relating to a material M are where applicable used:

M-i refers to the intrinsic or not intentionally doped material M, according to the terminology normally used in the microelectronics field for the suffix -i.

M-n refers to the n, n+ or n++ doped material M, according to the terminology normally used in the field of microelectronics for the suffix -n.

M-p refers to the p, p+ or p++ doped material M, according to the terminology normally used in the field of microelectronics for the suffix -p.

A substrate, film or layer “based” on a material M means a substrate, film or layer comprising this material M solely or this material M and optionally other materials, for example alloy elements, impurities or doping elements. Thus a layer made from a material based on germanium (Ge) may for example be a layer of germanium (Ge or Ge-i) or a layer of doped germanium (Ge-p, Ge-n) or a layer of a germanium-tin alloy (GeSn). A layer made from a material based on silicon (Si) may for example be a layer of silicon (Si or Si-i) or a layer of doped silicon (Si-p, Si-n) or a layer of an alloy of silicon-germanium (SiGe).

In the present patent application, the first, second and third directions correspond respectively to the directions carried by the axes x, y, z of a preferably orthonormal reference frame. This reference frame is depicted in the figures appended to the present patent application.

Hereinafter, the length is taken along the first direction x, the width is taken in the second direction y and the thickness is taken in the third direction z.

Hereinafter, the faces or sides are described, for reasons of clarity, as extending mainly along planes. These faces and sides are however not strictly included in said planes, taking account of manufacturing and/or measuring tolerances. These faces and sides may have curvatures and/or angular deviations outside said planes. The projection of a face or a side in the corresponding plane nevertheless preferably has a surface area greater than or equal to 80% of the surface area of the face or side.

“Lateral” means, according to circumstances: an orientation of the walls or layers normal to y, a growth by epitaxy directed along y, an arrangement along y of the various active regions or elements of the photodiode relative to each other.

In order to determine the geometry of the interfaces between the various layers, in particular between the sacrificial layer and the base layer, scanning electron microscopy (SEM) or transmission electron microscopy (TEM) analyses may be carried out.

An epitaxial growth of one material on another produces a clearly defined and substantially planar interface between these materials. In particular, a lateral epitaxial growth of Ge on a lateral face of Si produces a planar Si—Ge interface potentially without any structural defects. Such an Si—Ge interface obtained by the method according to the invention is illustrated in FIG. 17 appended to the present application.

These techniques also make it possible to observe the presence of a step bearing on the second layer and being situated between the first layer and the absorption medium of a photodiode according to the invention.

These techniques also make it possible to observe the presence of a step bearing on the second layer and being situated between the first layer and the absorption region of a photodiode according to the invention.

The chemical compositions of the various regions can be determined by means of the following well-known methods such as:
EDX or X-EDS, the acronym for “energy dispersive X-ray spectroscopy”.
   This method is well suited to analysing the composition of small devices such as photodiodes comprising thin layers or regions. It can be used on metallurgical sections in a scanning electron microscope (SEM) or on thin plates in a transmission electron microscope (TEM).
SIMS, the acronym for “secondary ion mass spectroscopy”.
ToF-SIMS, the acronym for “time of flight secondary ion mass spectroscopy”.
   These methods make it possible to access the elementary composition of the regions.

The structural quality of a layer can be studied by transmission electron microscopy (TEM).

Threading dislocations can in particular by observed by this technique and its derivatives (weak-beam and/or dark-field observation for example).

A first embodiment of the method according to the invention will now be described with reference to FIGS. 2 to 13B. The photodiode obtained by this first embodiment is a GeOI p-i-n lateral photodiode with double heterojunction comprising an absorption region A made from Ge-i interposed along y between a first contact region 1 made from Si-n and a second contact region 2 made from Si-p.

Advantageously, the absorption region is obtained by two successive epitaxial growths. A first lateral epitaxial growth of Ge makes it possible in particular to form a base layer. This first lateral epitaxial growth is followed by a second vertical epitaxial growth of Ge so as to form a structure layer on the base layer.

According to the first embodiment, a first step consists of providing a substrate 101 (FIG. 2), preferably SOI (the acronym for “silicon on insulator”; but materials other than silicon are also possible). The first layer 11 of silicon (also referred to as top Si hereinafter, preferably has a thickness of between 100 nm and 700 nm, preferably substantially equal to 300 nm. The second layer 12 is made from silicon dioxide, also referred to as BOX (the acronym for “buried oxide”), preferably has a thickness of between 10 nm and 2 μm, preferably between 10 nm and 100 nm, preferably substantially equal to 20 nm. The third layer 13 is made from silicon and may also be referred to as bulk Si hereinafter.

This substrate may have a diameter of 200 mm or 300 mm.

The following step consists of forming, on the first layer 11, the first and second contact regions 1, 2, preferably by ion implantation over the entire thickness of the top Si 11 (FIG. 3). The first contact region 1 may be n++ doped (concentration of dopants greater than 1×10²⁰ cm⁻³) or have a concentration of dopants greater than 1×10¹⁹ cm⁻³, for example between 1 to 3×10¹⁹ cm⁻³. It may have a width of around 15 μm or more.

The second contact region 2 may be p++ doped (concentration of dopants greater than 1×10²⁰ cm⁻³) or have a concentration of dopants greater than 1×10¹⁹ cm⁻³, for example between 1 to 3×10¹⁹ cm⁻³. It may have a width of around 15 μm or more.

The first and second contact regions 1, 2 may be adjacent along a plane zx.

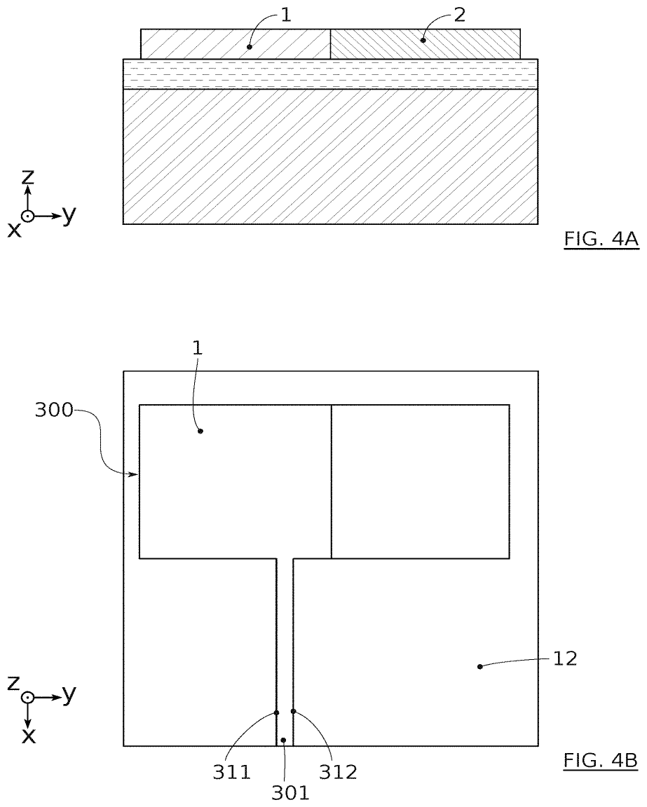

A step of defining a first pattern 300 comprising the first contact region 1, the absorption region A and the second contact region 2 is preferably performed by lithography and selective etching of the top Si over the entire height thereof (FIG. 4A). The selective etching of the top Si 11 with respect to the BOX 12 of silicon dioxide is widely known and is not characteristic of the present invention.

The definition of a second pattern in the form of a waveguide 301 is also performed by lithography and selective etching of the top Si over the entire height thereof (FIG. 4B), preferably when the first pattern 300 is defined.

This waveguide 301 is preferably configured to cooperate with the absorption region A by direct coupling. The waveguide 301 preferably has continuity with the absorption region A of the first pattern 300.

The waveguide 301 may be centred or not on the absorption region A. It may have a width of between 300 nm and 600 nm, preferably around 400 nm. The height thereof may be equal to that of the top Si 11.

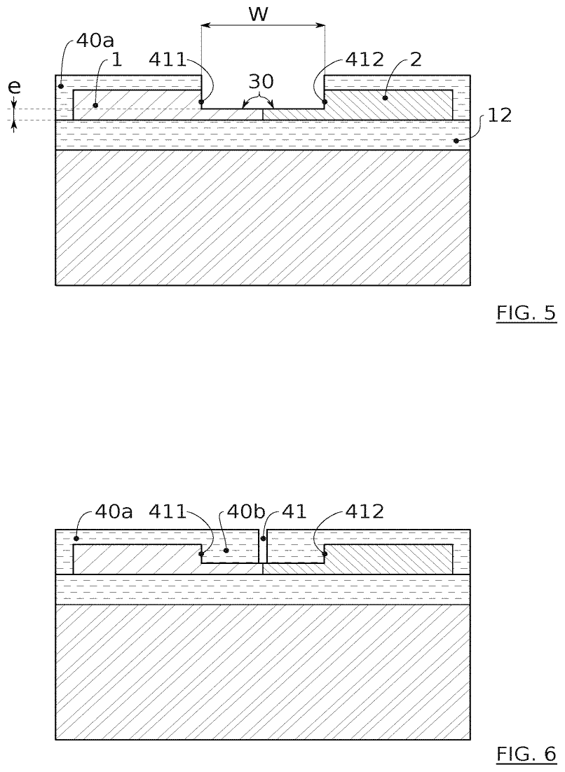

A first encapsulation step is next performed so as to cover the first and second patterns 300, 301 with an encapsulation layer 40a (FIG. 5).

The encapsulation layer 40a may be deposited by a chemical vapour deposition (CVD) method and is preferably conforming. The encapsulation layer 40a preferably has a thickness of between 100 nm and 300 nm. It may be a layer of oxide, for example a layer of silicon dioxide.

After encapsulation, a first opening is made by etching in the encapsulation layer 40a and in the top Si 11 over part of the height thereof, referred to as the top part.

This first opening is made between the first and second contact regions 1, 2, and also preferably partly in the first and second contact regions 1, 2. It is situated partly at the exit of the waveguide 301.

It comprises first and second lateral faces 411, 412 along zx, and an exit face along zy of the waveguide 301. These faces are also referred to as simply sides.

This first opening preferably has a width w between the first and second lateral faces 411, 412 of between 1 μm and 4 μm, for example around 3.2 μm.

It preferably has a length substantially equal to or slightly greater than the length of the first and second contact regions 1, 2, so as to separate said first and second contact regions 1, 2 on the top part.

In particular, the etching of the first opening and the definition of the waveguide 301 are preferably configured so that the longitudinal side 311 of the waveguide 301 is situated at a distance along y greater than or equal to 50 nm, preferably greater than or equal to 60 nm, of the side 411, in order to improve the coupling between the guided optical mode intended to be absorbed and the absorption region.

The etching of the first opening and the definition of the waveguide 301 are preferably configured so that the longitudinal side 312 of the waveguide 301 is situated at a distance along y greater than or equal to w/2+300 nm of the side 412, in order to prevent the guided optical mode being disturbed by a middle region along x between the sides 411, 412.

This first opening makes it possible to expose a sacrificial layer 30 in contact with the BOX 12, at the top part of the top Si 11, without exposing the underlying layer, here the BOX layer 12.

The etching of the encapsulation layer 40a and of the top Si 11 is known per se. It is configured so as to be stopped in the top Si 11 so as to form a sacrificial layer 30 having a residual thickness e preferably less than or equal to 50 nm, or even 20 nm, and/or greater than or equal to 10 nm (FIG. 5).

This sacrificial layer 30 of width w and thickness e comprises a part of the first and second contact regions 1, 2 in the bottom part. It provides continuity between the first and second contact regions 1, 2, and continuity with the waveguide 301.

A second encapsulation step is performed so as to cover the bottom and the sides based on Si of the first opening with an encapsulation layer 40b (FIG. 6).

The encapsulation layer 40b may be deposited by a chemical vapour deposition (CVD) method and is preferably conforming. The encapsulation layer 40b can fill the first opening. It may be an oxide layer, for example a layer of silicon dioxide.

At the end of these two encapsulation steps Chemical-Mechanical Polishing (CMP) is preferably performed so as to make the encapsulation layers 40a, 40b plane in order to obtain a planar surface in plane xy. This CMP polishing is configured to leave a thickness of encapsulation layer 40a of between 50 nm and 200 nm, so as to protect the first and second patterns 300, 301, in particular during the following etching steps.

After this encapsulation step, one or more openings 41 are formed through the encapsulation layer 40b over the entire thickness thereof so as to expose regions of the sacrificial layer 30 (FIG. 6). These openings 41 may be formed at the end of conventional lithography/etching steps. The openings 41 preferably have a circular cross section having a diameter of between 50 nm and 200 nm, preferably around 100 nm. More generally, the largest dimension in cross section in the plane xy of the openings 41 is preferably less than or equal to 200 nm and/or greater than or equal to 50 nm.

These openings 41 are preferably situated at a distance d along y from the first contact region 1 and/or from the second contact region 2, such that 0.6 μm<d≤1.5 μm and preferably d≈1.5 μm. This makes it possible to have the openings 41 away from the first contact region 1 and/or from the second contact region 2. The opening constitutes in fact singularities that may cause certain problems during following steps of the method, in particular during the lateral epitaxy of Ge in the cavity 42 formed by the at least partial removal of the sacrificial layer 30. Consequently it is advantageous to form the openings 41 as far away as possible from the first contact region 1 and/or from the second contract region 2 and/or from the absorption region A, so that the passage of the electric charges and/or of the light flow are not disturbed by the singularities formed by these openings 41.

The openings 41 are preferably evenly spaced apart between each other along x, for example by a distance D≤2d.

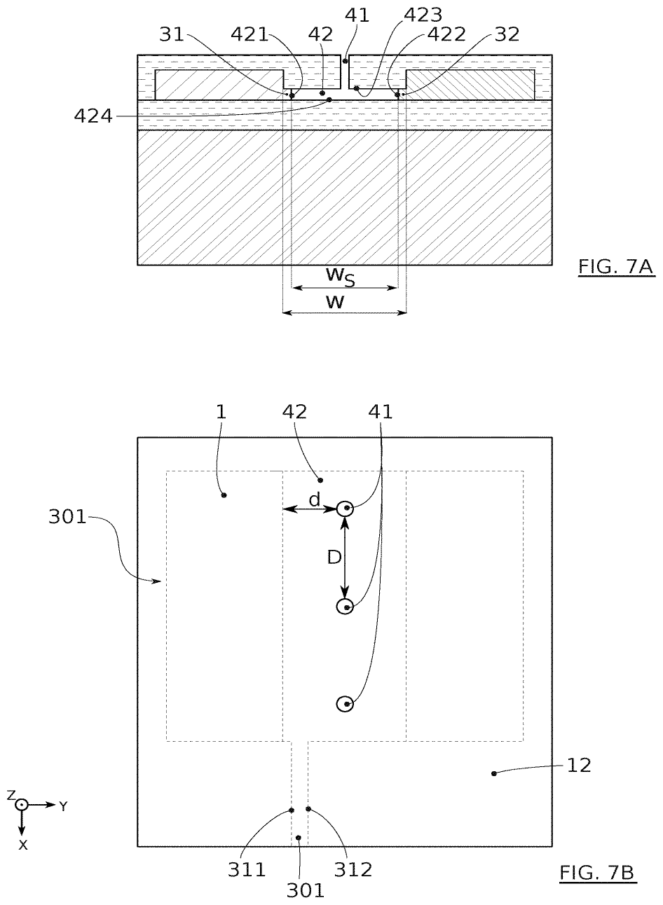

After the encapsulation layer 40b is opened, a step of etching of the sacrificial layer 30 selectively to the silicon dioxide (SiO2) of the encapsulation layer 40b and of the BOX 12 is carried out through the openings 41, so as to form alveoli underlying the openings 41 (FIG. 7A).

An alveolus corresponds to an opening 41 at least at the start of the etching. The alveoli are preferably centred on the corresponding openings 41.

These alveoli may advantageously have an overlap between them along y so as to form the cavity 42 at the end of etching, as illustrated in plan view in FIG. 7B.

This cavity 42 may therefore optionally result from a plurality of alveoli aggregated along y.

The positioning of the openings 41 is chosen so that the cavity 42 resulting from the alveoli underlying said openings 41 preferably has a rectangular cross section in the plane xy after etching.

The cavity 42 comprises a bottom wall formed by the bottom face 424 in SiO2 of the BOX 12. It comprises a top wall formed by the face 423 in SiO2 of the encapsulation layer 40b. It further comprises a first lateral face 421 and a second lateral face 422.

The cavity 42 preferably has a width ws between the first and second lateral faces 421, 422 of around 3 μm, a length of between 10 μm and 20 μm according to the number of openings 41 and a height between the bottom and top walls equal to the height of the sacrificial layer 30.

The width ws of the cavity 42 may advantageously be less than the width w of the first opening, so as to form a first step 31 between the BOX 12 and the first contact region 12, and a second step 32 between the BOX 12 and the second contact region 2.

The length of the cavity 42 may be less than the length of the first opening, so as to form a third step between the BOX 12 and the waveguide 301.

The cavity 42 is preferably centred with respect to the first opening, at least along y, so as to obtain first and second steps 31, 32 having an identical width.

In particular, the first opening may have a width w=3.2 μm, the cavity 42 may have a width ws of between 3 and 3.18 μm, and the first, second and third steps 31, 32 may have a width greater than or equal to 10 nm and/or less than or equal to 100 nm.

The etching is here configured so as to produce alveoli and subsequently the cavity 42 with controlled shape and orientation.

Along z, the alveoli advantageously extend over the entire height of sacrificial layer 30, between a bottom face 424 formed by an exposed part of the BOX 12 and a top face 423 formed by an exposed part of the encapsulation layer 40b.

Along x and y, the alveoli preferably extend along a substantially square cross section in the plane xy, the sides of the square being aligned along x and y.

In the case of the etching of the sacrificial layer 30 of Si, more generally for materials having a crystallographic structure of the centred cubic faces or zinc blend type, such a square form may advantageously be obtained by anisotropic etching.

Such anisotropic etching is in particular more rapid in the more dense planes of the crystal.

According to one embodiment, the etching, dry or wet, is configured so as to obtain an etching rate in the crystallographic directions [110] and [1-10], greater by at least 25%, preferably by at least 35%, than the etching rate in the directions [010] and [100].

The directions of the greatest etching rate will define the diagonals of a square, to within production tolerances. Because of this, the sides of the square are oriented in the crystallographic direction [100] or perpendicular to this direction.

The sides of each alveolus along x and y therefore preferably extend respectively in the crystallographic directions [100] and [010].

In the case of the etching of the sacrificial layer 30 of Si, a chemical etching using a flow of hydrochloric acid vapour HCl at a temperature below 850° C., and preferably below 820° C. can advantageously be used. The pressure in the etching chamber may be between 10 torr and atmospheric pressure, and preferably equal to 80 torr. The flow of HCl delivered may be between 1 slm and 25 slm (slm is the acronym for “standard litres per minute”) and preferably 15 slm. A flow of H₂ may also be added, for example between 1 slm and 40 slm, preferably 20 slm.

These etching conditions preferably make it possible to limit the etching regime by surface reaction, so as to produce an anisotropic etching of the sacrificial layer 30 of Si.

According to another possibility, the etching is a wet etching through the openings 41. In the case of the etching of the sacrificial layer 30 of Si, a preferably aqueous solution comprising potassium hydroxide may be used. Wet etching applied to a confined space makes it possible to obtain different etching rates along the crystallographic directions.

During the etching, the first and second lateral walls substantially parallel to the plane zx of each of the alveoli progress respectively in the direction of the first and second contact regions 1, 2, while the third and/or fourth lateral walls substantially parallel to the plane zy of two adjacent alveoli progress towards one another.

The etching time is preferably chosen so that the alveoli resulting from each opening 41 join together along y so as to form the cavity 42 at the end of etching.

These alveoli advantageously preserve the material, here the silicon, of the sacrificial layer 30 at least on the walls substantially parallel to the plane zx, so as to form the first and second lateral faces 421, 422 of the cavity 42.

The etching is preferably configured so that these first and second lateral faces 421, 422 along zx of the cavity 42 form respectively the step faces of the first and second steps 31, 32 of the first and second contact regions 1, 2.

The etching of the sacrificial layer 30 and the definition of the waveguide 301 are preferably configured so that the side 421 is situated in line with the longitudinal flank 311 of the waveguide 301 in order to optimise the optical coupling between the waveguide 301 and the absorption region subsequently formed.

According to an alternative possibility, the etching may be stopped when the first and second lateral faces 421, 422 along zx of the cavity 42 are substantially vertically in line with the first and second lateral faces 411, 412 along zx of the first opening, that is to say for a width ws substantially equal to the width w.

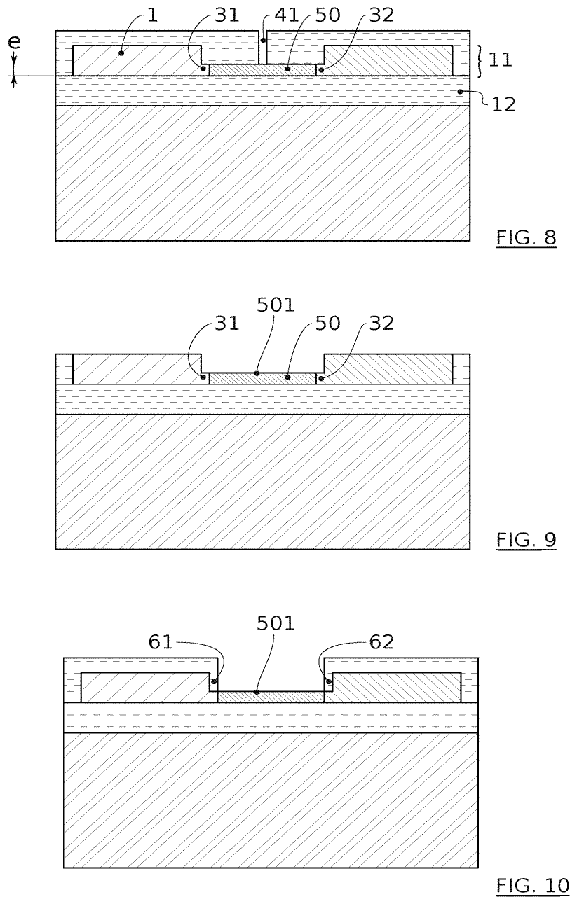

The cavity 42 is next advantageously filled by lateral epitaxy of germanium or of an alloy based on germanium, for example GeSn, so as to form the base layer 50 (FIG. 8).

Hereinafter, epitaxial growths of Ge are described. The invention also applies mutatis mutandis to epitaxial growths of GeSn.

The germanium is advantageously epitaxed onto the silicon-based lateral walls 421, 422 of the cavity 42 by a first lateral epitaxial growth.

This growth by lateral epitaxy is guided by the SiO2-based bottom and top walls of the cavity 42.

The growth front issuing from the first lateral wall 421 therefore propagates along y in the direction of the second contact region 2 in a well-controlled fashion. In a similar way, the growth front issuing from the second lateral wall 422 propagates along y in the direction of the first contact region 1 in a well controlled way.

The growth fronts join in a middle region substantially vertically in line with the openings 41.

The base layer 50 thus formed has a thickness equal to the residual thickness e, lying between 10 nm and 50 nm.

Such a thickness makes it possible to limit the appearance of structural defects in the base layer 50. In particular, the growth may be pseudomorphic, that is to say the epitaxy stresses (related in particular to the difference in mesh parameters between Si and Ge) can be released elastically during growth.

The crystalline quality of this base layer 50 of Ge can thus be optimised.

FIG. 17 shows a layer of Ge laterally up against a layer of Si. This layer of Ge has a thickness of 16 nm, and was obtained by lateral epitaxy between two layers of oxide forming the bottom and top walls according to the invention.

The layer of Ge thus obtained is free from structural faults. In particular, it is free from dislocations, in particular threading dislocations.

Moreover, the interface between the layer of Si and the layer of Ge is planar and well defined.

The lateral epitaxy of the germanium is preferably carried out using chemistry based on a germanium precursor GeH₄ or digermanium Ge₂H₆ in gaseous phase. An addition of hydrochloric acid HCl in gaseous phase can advantageously make it possible to prevent excessive fouling of the walls of the chamber of the epitaxy frame during epitaxy.

This germanium lateral epitaxy is preferably carried out at a “low” temperature of the order of 300° C. to 400° C. and a pressure of the order of 100 torr for a period of between 5 min and 15 min. Such a “low” temperature also makes it possible to limit the appearance of epitaxial defects in the base layer 50.

According to one possibility, the lateral epitaxy of germanium can be done in two stages, firstly at the “low” temperature and then at a “high” temperature of the order of 600° C. to 700° C. and at a pressure of the order of 20 torr for a period of between 5 min and 60 min. Such a “high” temperature makes it possible to benefit from high growth rates compatible with filling a cavity 42 of large dimensions. Such a “high” temperature also makes it possible to distribute more uniformly the dislocations present in the epitaxed germanium by virtue of greater mobility of sudden dislocations, and to potentially minimise the density thereof by recombination/annihilation of dislocations.

The lateral epitaxy of germanium is continued until the germanium covers the entire SiO2 bottom face 424 of the BOX 12.

It can be continued until the germanium at least partially fills the openings 41.

The base layer thus formed provides electrical continuity between the first and second steps 31, 32.

After filling of the cavity 42 by lateral epitaxy of the germanium, an optional thermal cycling step, under H₂ at temperatures varying between 750° C. and 890° C. over short cycles of a few minutes, can advantageously reduce the density of dislocations in the germanium.

The encapsulation layers 40a, 40b are next removed, at least partially, so as to expose the top face 501 of the base layer 50 (FIG. 9). Wet etching of the SiO2 selectively to Si and Ge can be implemented so as to remove these encapsulation layers 40a, 40b. Such etching is widely known to persons skilled in the art.

Optionally, a smoothing step comprising for example an anisotropic etching of the base layer 50 can be carried out so as to remove any protrusion of germanium at the openings 41.

This smoothing step is configured so as to improve the planeness of the top face 501 of the base layer 50.

Another step, for example in cleaning, for preparing the surface of the top face 501 can also be performed, prior to the second vertical epitaxial growth of Ge.

A step of masking of the faces based on Si can advantageously be performed, so as to expose solely the top face 501 of the base layer 50 of Ge (FIG. 10).

The first and second contact regions 1, 2, the first, second and third steps 31, 32, and/or the sides of the first opening can thus be covered with a layer made from a dielectric material, for example SiO2 or a silicon nitride (SiN) that is lightly stressed.

Lateral layers 61, 62 of SiO2 or SiN are thus advantageously formed.

The first lateral layer 61 covering the first lateral face 411 may have a width w1 of between 10 nm and 100 nm.

The second lateral layer 62 covering the second lateral face 412 may have a width w2 of between 10 nm and 100 nm.

A third lateral layer covering the exit face of the waveguide 301 may have a dimension along x of between 10 nm and 100 nm.

Ideally, the first lateral layer 61 and/or the second lateral layer 62 have the same width as respectively the first step 31 and/or the second step 32, such that w1=(w−ws)/2 and/or w2=(w−ws)/2.

The free lateral side of the first lateral layer 61 is consequently preferably vertically in line with the side 421. The free lateral side of the second lateral layer 62 is consequently preferably vertically in line with the side 422.

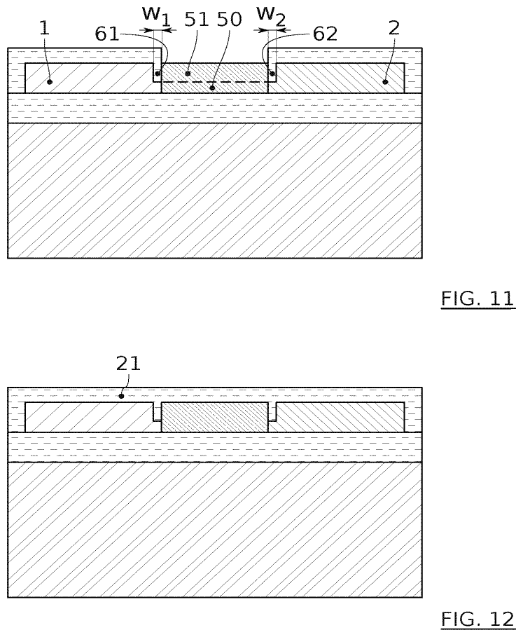

These first, second and third lateral layers 61, 62 advantageously make it possible to guide the second vertical epitaxial growth of Ge (FIG. 11).

The first and second lateral layers 61, 62 are preferably made from a material with a low refractive index. They thus make it possible to improve the optical compartment of a light wave in the absorption region A. These first and second lateral layers 61, 62 rest on the first and second steps 31, 32, causing both an optical confinement by contrast of refractive indices, and a geometric optical confinement.

In particular, first and second lateral layers 61, 62 of SiO2 exhibit a greater difference in refractive index with the Ge of the absorption region A. This increases the optical confinement said to be by contrast of indices.

The first and second steps 31, 32 form in the plane zy a transverse profile “in a ridge”. This increases the geometric optical confinement.

The third lateral layer is preferably configured so as to optimise the optical coupling between the waveguide 301 and the Ge of the absorption region A, that is to say so as to optimise the transmission of a light wave propagating from the waveguide towards the absorption region A in a given optical mode.

In particular, for a dimension along x of less than or equal to 20 nm, a third lateral layer of SiO2 makes it possible to transmit a Gaussian mode of a light wave having a wavelength of around 1.55 μm almost without optical losses. For a dimension along x greater than or equal to 40 nm, a lightly stressed third lateral layer of SiN, having a refractive index greater than SiO2, makes it possible to limit the optical losses in the transmission of a Gaussian mode of a light wave having a wavelength of around 1.55 μm.

The second growth by vertical epitaxy of Ge takes place from the top face 501 of the base layer 50. This base layer 50 therefore forms a nucleus or a germination layer for the growth of the structure layer 51.

The lateral layers 61, 62 prevent a parasitic growth of Ge on the sides of the first opening and, preferably, on the steps 31, 32.

The growth front issuing from this top face 501 therefore propagates along z in a well controlled manner.

The structure layer 51 thus formed has optimised crystalline quality.

At the end of the vertical epitaxy, the growth front corresponds to the top surface of the structure layer 51.

This top surface may be situated either below a plane comprising the surfaces of the contact regions 1, 2, or substantially in this plane, flush with the surfaces of the contact regions 1, 2, or above this plane, projecting beyond the surfaces of the contact regions 1, 2.

In the latter case, subsequent polishing may be carried out in order to level the surfaces of the contact regions 1, 2 and the top surface of the structure layer 51. This levelling is however optional.

The vertical epitaxy of the germanium is preferably carried out using chemistry based on a germanium precursor GeH₄ or digermanium Ge₂H₆ in gaseous phase. An addition of hydrochloric acid HCl in gaseous phase may advantageously make it possible to prevent excessive fouling of the walls of the chamber of the epitaxy frame during epitaxy.

This vertical epitaxy of germanium is preferably carried out at the “high” temperature mentioned above for lateral epitaxy, around 600° C. to 700° C., so as to benefit from high growth rates compatible with filling of a first large opening.

According to one possibility, the vertical epitaxy can be done in two stages as for the lateral epitaxy, first of all at the “low” temperature mentioned above, around 300° C. to 400° C., then at the “high” temperature.

The etching of the top Si 11 in order to form the first opening and the cavity 42, and the first and second epitaxial growths of germanium, can advantageously take place in the same frame, so as to avoid oxidation of the lateral 421, 422 and top 501 faces.

A smoothing step comprising for example a deposition of a dielectric material, preferably SiO2, and a chemical-mechanical polishing (CMP) are performed after the second growth, so as to obtain an encapsulation layer 21 (FIG. 12).

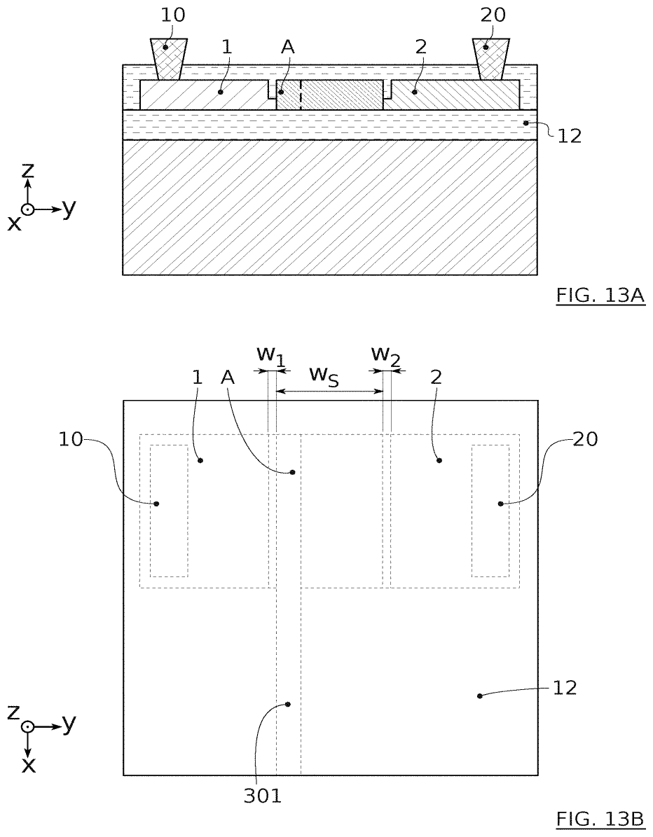

The following steps may be conventional steps of forming metal contacts, comprising in particular the formation of through vias at the first and second contact regions 1, 2 (FIG. 13A), the deposition of metal contacts 10, 20 in the vias and optional rapid thermal annealings (RTAs) for activating the contacts 10, 20.

A GeOI p-i-n lateral photodiode with double heterojunction is thus advantageously obtained (FIGS. 13A and 13B).

The first and second steps 31, 32 of this photodiode constitute carrier-injection regions. In order to compensate for a small thickness of these carrier-injection zones, the doping of the first and second steps 31, 32 can be increased, for example by a step of implanting a higher dose after having exposed the sacrificial layer 30. A dose higher than or equal to 5.10¹⁹ cm⁻³ may suit.

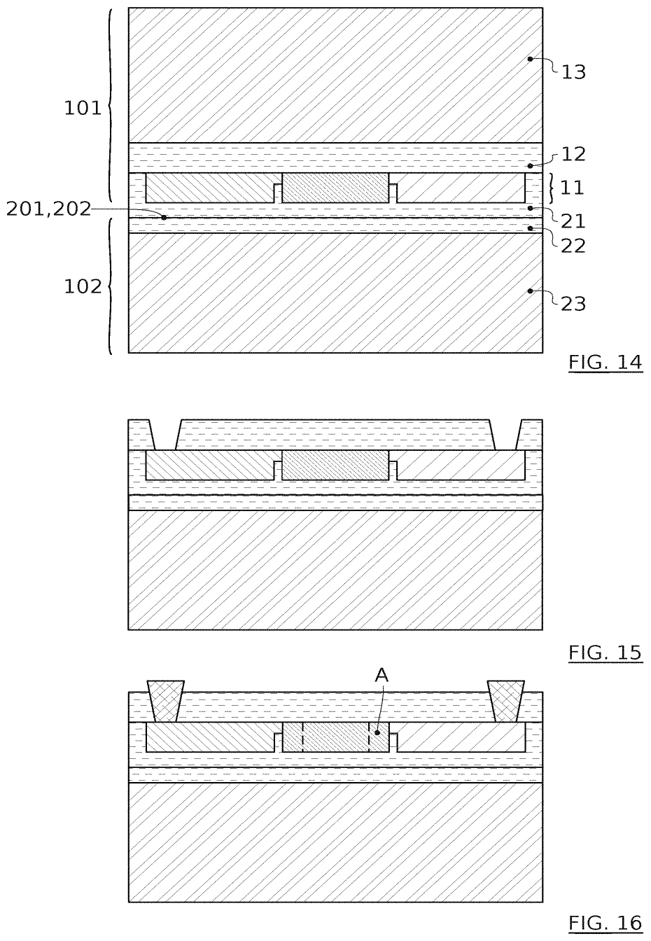

A second embodiment of the method according to the invention will now be described with reference to FIGS. 14 to 16. The photodiode obtained by this second embodiment is a lateral p-i-n photodiode with double heterojunction issuing from a first substrate 101 and transferred onto a second substrate 102.

Only the distinct features of the first embodiment are described below, the other features not described being deemed to be identical to those of the first embodiment described above with reference to FIGS. 2 to 13B.

In this second embodiment, the first substrate 101 is preferably an SOI substrate.

The first steps of this second embodiment are steps common with those of the first embodiment illustrated in FIGS. 4 to 12. They consist essentially of forming the first and second contact regions 1, 2, defining the first and second patterns 301, 302 forming the first opening then the cavity 42, making the first and second germanium growths and encapsulating the whole.

These steps are preferably performed according to the same conditions as those disclosed previously in the first embodiment of the invention.

In this second embodiment, the smoothing step performing the encapsulation 21 comprises a deposition of oxide SiO2, for example a CVD deposition using a TEOS (tetraethylorthosilicate) precursor, so as to cover at least the germanium of the structure layer.

The encapsulation layer 21 is a layer of oxide 21. This layer of oxide 21 preferably has a uniform thickness, lying between a few tens of nanometres and a few hundreds of nanometres, and a free face 201.

The second substrate 102 may for example be a silicon substrate 23 comprising optionally optoelectronic or microelectronic devices on a face referred to as the active face. This second substrate 102 may also comprise III-V materials and/or devices of the photon on silicon type on its active face.

A deposition of oxide, for example by CVD using a TEOS precursor or by thermal oxidation, can be carried out on the active face of the second substrate 102 so as to form a layer of oxide 22 with a thickness of between a few hundreds of nanometres and a few microns.

The sum of the thicknesses of the layer of oxide 21 and the layer of oxide 22 is preferably between 800 nm and 900 nm.

The layer of oxide 22 has a free face 202.

Direct bonding between the first and second substrates 101, 102 is preferably effected.

A step of preparing the surface of the free faces 201, 202 of the first and second substrates 101, 102, comprising for example cleaning and hydrolysis, is preferably carried out. The cleaning can be done for example in a bath of ozone-enriched deionised water. The hydrolysis can be carried out for example in a solution of ammonium peroxide (APM—ammonium peroxide mixture) at 70° C.

After preparation of the surfaces, the free face 201 of the oxide 21 of the first substrate 101 is put in contact with the free face 202 of the oxide 22 of the second substrate 102, at ambient temperature and pressure.

Annealing at 400° C. for two hours can then be performed so as to analyse the direct bonding by molecular adhesion between the oxides 21, 22 (FIG. 14).

The bulk Si 13 of the first substrate 101 can then be removed, for example by trimming and abrasion over at least 95% of its initial thickness and then by selective etching in a solution based on tetramethylammonium hydroxide (TMAH), so as to expose the BOX 12. Such etching may have an Si/SiO2 selectivity ratio of around 5000/1.

This possibility makes it possible to obtain on the surface a layer of oxide with a very well controlled thickness formed by the exposed BOX 12. Some photonic components requiring such a layer of oxide with a very well controlled thickness can consequently be formed on the exposed BOX 12. For example, a capacitive modulator comprising electrodes on either side of the BOX 12 with very well controlled thickness can advantageously be formed. Such a modulator may in fact have improved precision with regard to its capacity. Its functioning can thus advantageously be optimised.

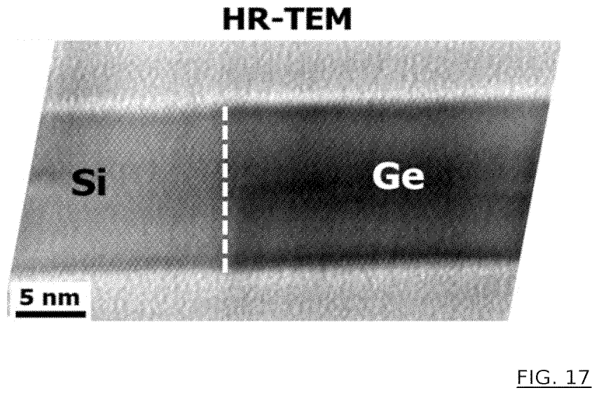

Through vias at the first and second contact regions 1, 2 of the photodiode can next be formed (FIG. 15), and metal contacts 10, 20 can next be deposited at the vias and then activated (FIG. 16).

Advantageously, the metal contacts 10, 20 have metal surfaces fitting flush with the first and second contact regions 1, 2, in a plane defining a top border of the absorption region A. The transportation of charges and/or the optical confinement of such a lateral p-i-n photodiode is improved compared with a solution requiring etching vias through a germination layer 111.

A GeOI lateral p-i-n photodiode with double heterojunction transferred onto a second substrate 102 can thus be produced (FIG. 16).

A chip comprising at least one GeOI lateral p-i-n photodiode with double heterojunction on a first face of the BOX 12, and for example at least one capacitive modulator partly on a second face of the BOX 12 opposite to the first face can thus advantageously be obtained.

The method according to the invention makes it possible to obtain GeOI p-i-n lateral photodiodes. Such photodiodes also constitute a separable aspect of the invention.

The invention is not limited to the embodiments described above and extends to all embodiments covered by the claims.

1. A method for producing a photodiode comprising a first contact region, a second contact region and an absorption region (A) all juxtaposed parallel to a first direction (x) of a basal plane, said absorption region (A) being situated between the first and second contact regions along a second direction (y) of the basal plane, said method comprising:
providing a first substrate comprising a stack in a third direction (z) of a first layer based on a first material on a second layer based on a second material different from the first material,
forming the first contact region in the first layer,
forming the second contact region in the first layer,
forming the absorption region (A) in the first layer,
wherein the absorption region (A) is formed by at least one first growth of a base layer, referred to as lateral growth, followed by at least one second growth of a structure layer, referred to as vertical growth, the first growth comprising successively:
removing the first material in the absorption region over the entire thickness of the first layer so as to expose a bottom face based on the second material, and at least one face based on the first material substantially normal to the basal plane, referred to as the lateral face, having an edge in contact with said exposed bottom face,
forming the base layer made from a third material by epitaxial growth of said third material from at least one lateral face, said growth being mainly directed in the second direction and at least partially guided by at least one wall parallel to the basal plane, so that the base layer covers all the bottom face,
the second growth comprising successively:
exposing a top face of the base layer parallel to the basal plane,
forming the structure layer from a fourth material by epitaxial growth on said fourth material in the third direction from the top face of the base layer.

2. The method according to claim 1, wherein the first growth comprises the following for removing the first material over the entire thickness of the first layer:
removing the first material of the first layer while keeping a sacrificial layer based on the first material on the second layer, said sacrificial layer having a residual thickness e in the third direction and a width w in the second direction,
encapsulating the sacrificial layer with an encapsulation layer made from an encapsulation material different from the first material,
forming at least one opening through the encapsulation layer so as to expose a region of the sacrificial layer,
forming a cavity of width ws such that ws≤w by removing the first material over the entire residual thickness of the sacrificial layer through at least one opening, so as to expose the bottom face based on the second material, at least one lateral face and a face of the encapsulation layer, the cavity comprising said at least one lateral face, a bottom wall formed by said bottom face and a top wall parallel to the basal plane and based on the encapsulation material, formed by said face of the encapsulation layer,
so that the epitaxial growth for forming the base layer is at least partially guided by said bottom and top walls, the base layer having a thickness equal to the residual thickness e.

3. The method according to claim 1, wherein the first, third and fourth materials each have a crystallographic structure of the cubic type, and wherein the first direction (x) corresponds to a crystallographic orientation of type [100], the second direction (y) corresponds to a crystallographic orientation of type [010], and the third direction (z) corresponds to a crystallographic orientation of type [001].

4. The method according to claim 2, wherein the first, third and fourth materials each have a crystallographic structure of the cubic type, and wherein the first direction (x) corresponds to a crystallographic orientation of type [100], the second direction (y) corresponds to a crystallographic orientation of type [010], and the third direction (z) corresponds to a crystallographic orientation of type [001], and wherein the removal of the first material during the formation of the cavity is done by etching, said etching being configured so as to produce an etching rate at least 25% greater, in crystallographic direction [110] and [1-10], than in crystallographic directions [010] and [100] of the first material of the first layer, and preferably at least 35% greater.

5. The method according to claim 1, wherein the second growth further comprises, before the formation of the structure layer, the following:
forming at least one lateral layer having lateral walls substantially normal to the basal plane made from a material different from the first material, said at least one lateral layer bearing on a face parallel to the basal plane comprising the top face of the base layer,
so that the epitaxial growth for forming the structure layer is at least partially guided by said lateral walls.

6. The method according to claim 2, wherein the second growth further comprises, before the formation of the structure layer, the following:
forming at least one lateral layer having lateral walls substantially normal to the basal plane made from a material different from the first material, said at least one lateral layer bearing on a face parallel to the basal plane comprising the top face of the base layer, so that the epitaxial growth for forming the structure layer is at least partially guided by said lateral walls, and
wherein the formation of at least one lateral layer comprises the following:
partially removing the encapsulation layer so as to expose the face parallel to the basal plane comprising the top face of the base layer leaving part of the encapsulation material so as to form the at least one lateral layer.

7. The method according to claim 2, wherein the second growth further comprises, before the formation of the structure layer, the following:
forming at least one lateral layer having lateral walls substantially normal to the basal plane made from a material different from the first material, said at least one lateral layer bearing on a face parallel to the basal plane comprising the top face of the base layer,
so that the epitaxial growth for forming the structure layer is at least partially guided by said lateral walls, and
wherein the second vertical growth comprises the following for forming at least one lateral layer:
completely removing the encapsulation layer so as to expose the face parallel to the basal plane comprising the top face of the base layer,
forming at least one lateral layer from a material taken from a silicon oxide and a silicon nitride.

8. The method according to claim 2, wherein the width ws of the cavity is strictly less than the width w of the sacrificial layer so that the sacrificial layer forms at least one step between the second layer and the first layer.

9. The method according to claim 5, wherein at least one lateral layer comprises a first lateral layer in contact with at least one face of the first contact region substantially normal to the second direction, said first lateral layer having a width w1 in the second direction greater than or equal to 10 nm and/or less than or equal to 100 nm.

10. The method according to claim 5, wherein at least one lateral layer comprises a second lateral layer in contact with at least one face of the second contact region substantially normal to the second direction, said second lateral layer having a width w2 in the second direction greater than or equal to 10 nm and/or less than or equal to 100 nm.

11. The method according to claim 1, wherein the base layer has a thickness e in the third direction greater than or equal to 10 nm and/or less than or equal to 50 nm.

12. The method according to claim 1, wherein the formation of at least one from the first and second contact regions is done by ion implantation prior to the formation of the absorption region.

13. The method according to claim 1, further comprising a formation in the first layer of a waveguide in direct coupling with the absorption region (A).

14. The method according to claim 2, wherein at least one opening has a closed contour and is distant from the first contact region by a distance d in the second direction (y) such that 0.6 μm<d<1.5 μm.

15. The method according to claim 1, wherein the first material is silicon or germanium, the second material is a dielectric material, the third material is taken from germanium and germanium-tin, and the fourth material is taken from germanium, germanium-tin, gallium arsenide and indium phosphide.

16. The method according to claim 1, wherein the first substrate comprises a third layer, so that the second layer is interposed between the first and third layers in the third direction (z), the method further comprising a sequence of flipping the photodiode on a second substrate, said sequence comprising the following:
providing a second substrate,
bonding the second substrate by molecular adhesion to the first substrate in the third direction (z), the first layer of the first substrate being turned facing the second substrate,
removing the third layer from the first substrate,
forming, through the second layer of the first substrate, first and second metal contacts respectively on the first and second contact regions.

17. The method according to claim 1, wherein the epitaxial growth for forming the base layer is done at a first temperature T1 of between 300° C. and 450° C. and the epitaxial growth for forming the structure layer is done at a second temperature T2 of between 300° C. and 750° C.

18. A photodiode comprising a first contact region, a second contact region and an absorption region (A) all formed in a first layer based on a first material and juxtaposed so as to extend parallel in a first direction (x), said absorption region (A) being situated between the first and second contact regions along a second direction (y), the first layer being in contact with a second layer based on a second material different from the first material, in a third direction (z) perpendicular to the first and second directions (x, y),
wherein the absorption region (A) is formed in a thickness of the first layer and comprises at least one third material different from the first and second materials and directly in contact with the second material of the second layer, and wherein at least one from the first and second contact regions has a step facing the other one from the first and second contact regions, said step bearing on the second layer and being situated between the first layer and the absorption region (A).

19. The photodiode according to claim 18, wherein the step has a thickness e in the third direction greater than or equal to 10 nm and/or less than or equal to 50 nm.

20. The photodiode according to claim 18, wherein the step has a width wi in the second direction greater than or equal to 10 nm and/or less than or equal to 100 nm.

21. The photodiode according to claim 18, further comprising at least one lateral layer bearing on the step and situated between the first layer and the absorption region (A), said at least one lateral layer being made from a material taken from a silicon oxide and a silicon nitride.
